(19) United States
(12) Patent Application Publication
(10) Pub. No.: US 2008/0157345 A1
(43) Pub. Date: Jul. 3, 2008

(54) CURVED HEAT SPREADER DESIGN FOR ELECTRONIC ASSEMBLIES

(76) Inventors: Daoqiang LU, Chandler, AZ (US); Wei SHI, Gilbert, AZ (US)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/618,263

(22) Filed: Dec. 29, 2006

(51) Int. Cl. H01L 23/34; H01L 21/00

(52) U.S. Cl. 257/712; 438/122; 257/E23.08; 257/E21.001

(57) ABSTRACT

The formation of electronic assemblies is described. One embodiment relates to an electronic assembly including a die coupled to a substrate, the die including a curved surface. The assembly also includes a thermal interface material having a first curved surface and a second curved surface, the first curved surface coupled to the curved surface of the die. The assembly also includes a heat spreader having a curved surface, wherein the curved surface of the heat spreader is coupled to the second curved surface of the thermal interface material. Other embodiments are described and claimed.

### RELATED ART

Integrated circuits may be formed on semiconductor wafers that are formed from materials such as silicon. The semiconductor wafers are processed to form various electronic devices thereon. The wafers are diced into semiconductor chips, which may then be attached to a package substrate using a variety of known methods. In one known method for attaching a chip (also known as a die) to a substrate, the die may have solder bump contacts which are electrically coupled to the integrated circuit. The solder bump contacts extend onto the contact pads of a package substrate, and are typically attached in a thermal reflow process. Electronic signals may be provided through the solder bump contacts to and from the integrated circuit.

Operation of the integrated circuit generates heat in the device. As the internal circuitry operates at increased clock frequencies and/or higher power levels, the amount of heat generated may rise to levels that are unacceptable unless some of the heat can be removed from the device. Heat is conducted to a surface of the die, and should be conducted or convected away to maintain the temperature of the integrated circuit below a predetermined level for purposes of maintaining functional integrity of the integrated circuit.

One way to conduct heat from an integrated circuit die is through the use of a heat spreader, which may be thermally coupled to the die through a thermal interface material. Materials such as certain solders may be used as thermal interface materials and to couple the heat spreader to the die. A heating operation at a temperature greater than the melting point of the solder is carried out to form a solder connection between the die and the heat spreader. The joined package is then cooled and the solder solidified.

### BRIEF DESCRIPTION OF THE DRAWINGS

Embodiments are described by way of example, with reference to the accompanying drawings, which are not drawn to scale, wherein:

FIGS. 1A-1D illustrate the formation of a electronic assembly including a curved heat spreader coupled to a curved die with a thermal interface material between the heat spreader and the die, in accordance with certain embodiments;

FIG. 2 illustrates the measurement of the curvature of a surface, in accordance with certain embodiments;

FIGS. 3A-3B illustrate the formation of a heat spreader having a curved surface, in accordance with certain embodiments;

FIG. 4 illustrates a flow chart of certain operations for forming an assembly including a heat spreader bonded to a die on a substrate, in accordance with certain embodiments;

FIGS. 5(A)-5(B) illustrate metallization layers that may be formed on the heat spreader and the die, in accordance with certain embodiments; and

FIG. 6 illustrates an electronic system arrangement in which certain embodiments may find application.

### DETAILED DESCRIPTION

Certain embodiments relate to the formation of electronic assemblies, including the use of a curved heat spreader coupled to a warped die through a thermal interface material.

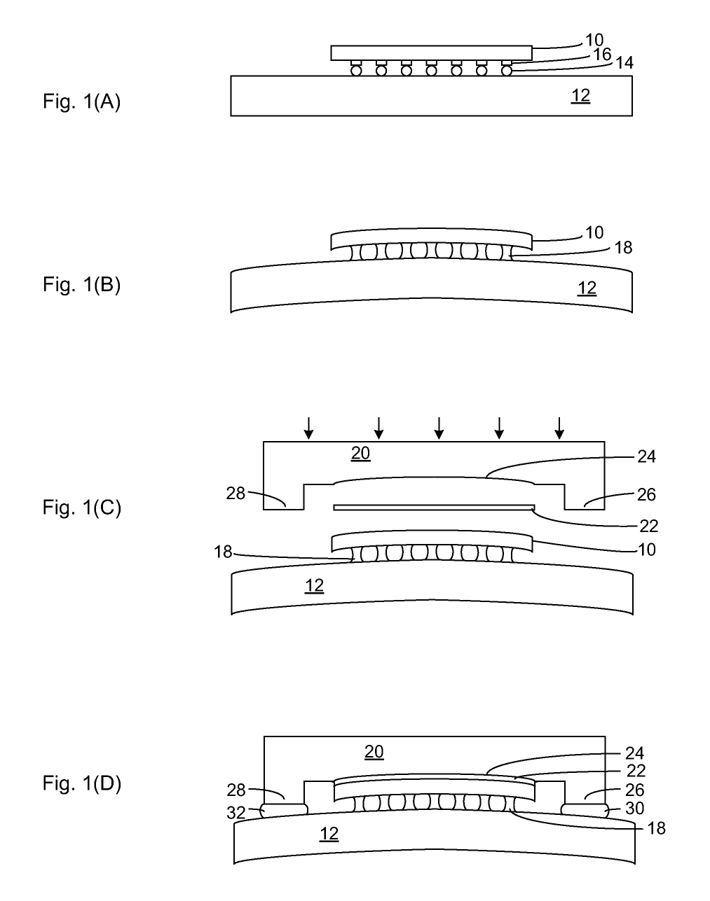

FIGS. 1A-1D illustrate processing operations during the formation of an electronic assembly, in accordance with certain embodiments. As illustrated in FIG. 1(A), a die 10 is positioned on a package substrate 12. The die 10 includes solder bumps 16 and the substrate 12 includes solder bumps 14. Upon heating, the solder bumps 14 and 16 will reflow and form bond 18 that couples the die 10 to the substrate 12. As illustrated in FIG. 1(B), due to thermal expansion mismatch, both the die 10 and the substrate 12 are warped.

As illustrated in FIG. 1(C), a heat spreader 20 and thermal interface material 22 are positioned over the die 10 and substrate 12, and a force may be applied as indicated by the arrows, to bring the components together. The force may be applied using, for example, a clip such as known in the art. The thermal interface material 22 may in certain embodiments be a solder material in the form of a solder preform. In other embodiments, the thermal interface material 22 may be formed from a different material, for example, a polymer with particles of metal or ceramic therein. The heat spreader 20 includes a curved surface 24 designed to accept the curvature of the die 10. Such a structure enables the use of a thermal interface material 22 having a small thickness between the die 10 and heat spreader 20, which enhances the thermal transfer characteristics of the assembly and decreases the overall height of the assembly. The thickness of the thermal interface material between the die and heat spreader is also known as the bond-line thickness. While a small thickness enhances heat transfer, it may also cause problems when a flat heat spreader is used with a curved die, because the thin preform may not be able to fill the gap between the curved die and the heat spreader. As a result, in accordance with certain embodiments, the heat spreader 20 is designed with a curved surface 24, as illustrated in FIG. 1(C), adapted to the curvature of the die 10, so that the thermal interface material 22 can be made thin.

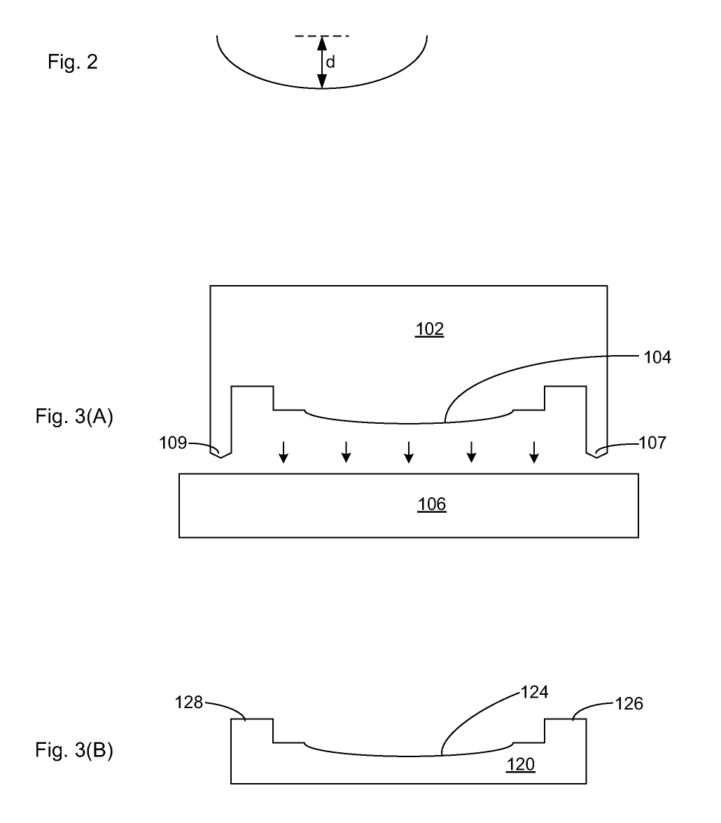

In certain embodiments, the depth of curvature of the die 10 and the depth of curvature of the heat spreader curved surface 24 are each in the range of 30 μm to 300 μm. As used herein, the depth of curvature of a surface refers to the depth d relative to the lowest part of the surface, as illustrated in FIG. 2. The curved surface of the heat spreader does not necessarily need to have an identical depth of curvature to that of the die. It is believed that in certain embodiments, a variation of about 40 μm or less between the depth of curvature of the die and the depth of curvature of the heat spreader is adequate to obtain a suitable bond.

FIG. 1(D) illustrates the assembly with the components joined together. When the thermal interface material 22 is a solder, then the joining takes place by reflowing the solder to form the bond between the die 10 and heat spreader 20. Metallization layers may be formed on the die 10 and the heat spreader 20, to promote bonding of the thermal interface material 22 to the die 10 and the heat spreader 20. Examples of metallization structures which may be used in accordance with certain embodiments are illustrated in FIGS. 5(A) and 5(B), which are discussed below. The thermal interface material 22 takes the shape of the curved surfaces of the die 10 and the heat spreader surface 24 and fills the gap therebetween. In certain embodiments, as illustrated in FIG. 1(D), the thermal interface material 22 may be substantially uniform in thickness between the die 10 and heat spreader 20. When a solder is used as the thermal interface material, the heating process to reflow the solder may also release a small amount of the die warpage. In addition, the application of force to the heat spreader to hold the stack together may result in the heat spreader curvature being reduced by a small amount.

In the embodiment illustrated in FIG. 1(D), the heat spreader 20 acts as a lid to cover the die 10, and includes leg regions 26, 28 which are bonded to the package substrate 12 using a sealant 30, 32. The sealant may in certain embodiments be a polymer material.

Embodiments such as described above are well suited for assemblies in which a large thin die and a thin thermal interface material are used, because a large thin die is more likely to have substantial warpage and a thin thermal interface material may not be thick enough to fill the gap between the die and heat spreader resulting from the curvature of the warped die. One embodiment includes an assembly with the following dimensions: a die thickness of approximately 300 μm, a die area of approximately 22 mm by 33 mm, and a solder preform thermal interface material having a thickness of approximately 100 μm.

FIGS. 3(A) and 3(B) illustrate a method for forming a heat spreader having a curved surface in accordance with certain embodiments. A stamping head 102 having a curved surface 104 is used to stamp a block of material 106 to form the heat spreader 120 having curved surface 124. The stamping head 102 may also have regions 107, 109 to form the leg regions 126, 128 on the heat spreader 120. In certain embodiments, in order to determine the amount of curvature on the surface 104 of the stamping head 102, a number of partial assemblies of a die coupled to a substrate may be formed and the curvature of the die measured using a suitable measuring method. Alternatively, a suitable computer simulation method may be used to predict the amount of curvature that will be needed to ensure a satisfactory joint will be formed between a heat spreader and die. In addition, alternative methods for forming a curved surface on a heat spreader may be used, including, but not limited to, machining and grinding.

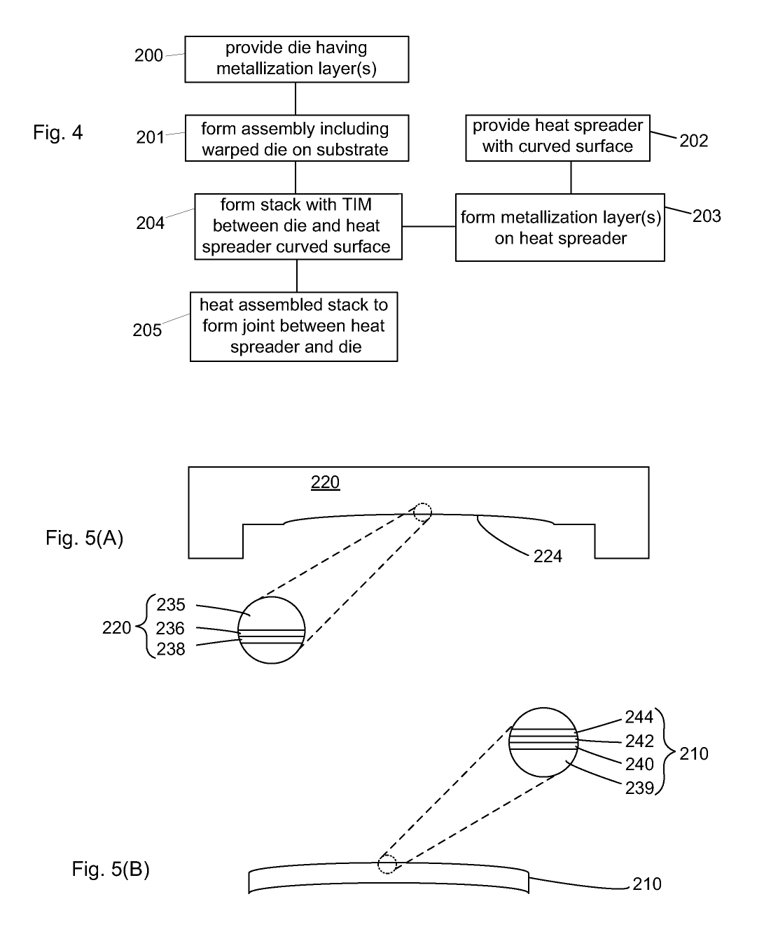

FIG. 4 is a flow chart showing a number of operations in accordance with certain embodiments for forming an assembly including a curved die and heat spreader. Box 200 is providing a die having one or more metallization layers. In certain embodiments, the metallization layers act to promote bonding with a thermal interface material such as a solder. Box 201 is forming a die on substrate assembly that includes a warped die. Box 202 is providing a heat spreader with a curved surface adapted to match or nearly match the a curvature of the warped die. In certain embodiments, it is also suitable to form one or more metallization layers on the heat spreader surface, in order to promote bonding with the thermal interface material. Such layers are often formed from metals. Box 203 is plating the metallization layers onto the curved surface of the heat spreader. Other methods for forming the metallization layers could also be used.

Box 204 is forming a stack including a thermal interface material (TIM) such as a solder positioned between the die and the heat spreader. Box 205 is heating the stack to bond the heat spreader to the die through the thermal interface material. In certain embodiments, the heating may be carried out in a vacuum oven and a flux may be used during the reflow operation. A clip may be used to hold the assembly together during the heating process. A nearly void-free bond may then be obtained. Suitable fluxless processes for joining the components may also be used, for example, processes in which a native oxide on the solder preform is removed and the heating is carried out in a non-oxygen environment. With a fluxless process, it may be possible to obtain a void-free bond, because void formation due to flux residue can be eliminated.

In certain embodiments, the heat spreader comprises copper, the thermal interface material is a solder comprising indium and/or tin, and the heat spreader metallization layers include nickel and gold. Other materials may also be used for the various layers. One or more metallization layers may also be formed on the surface of the die, using, for example, sputtering. Such layers on the die may in certain embodiments include layers of titanium, nickel, and gold, or layers of titanium, nickel-vanadium, and gold. Examples including a heat spreader 220 and a die 210, each including a plurality of metallization layers, are illustrated in FIGS. 5(A) and 5(B). As seen in FIG. 5(A), the heat spreader 220 includes a curved surface 224 having metallization layers 236 and 238 on a base 235 formed from, for example, copper. As noted above, in certain embodiments, metallization layer 236 comprises nickel and metallization layer 238 comprises gold. As seen in FIG. 5(B), the die 210 includes metallization layers 240, 242, 244 on the die base 239 formed from, for example, silicon. In certain embodiments, as described above, the metallization layer 240 comprises titanium, the metallization layer 242 comprises nickel, and the metallization layer 244 comprises gold. In an alternative embodiment, the metallization layer 242 comprises nickel-vanadium.

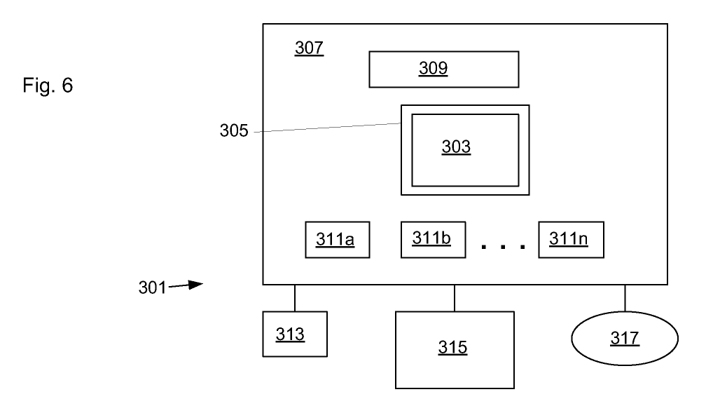

Assemblies including a heat spreader and die joined together as described above may find application in a variety of electronic components. FIG. 6 schematically illustrates one example of an electronic system environment in which aspects of described embodiments may be embodied. Other embodiments need not include all of the features specified in FIG. 6, and may include alternative features not specified in FIG. 6.

The system 301 of FIG. 6 may include at least one central processing unit (CPU) 303. The CPU 303, also referred to as a microprocessor, may be a die which is attached to an integrated circuit package substrate 305, which is then coupled to a printed circuit board 307, which in this embodiment, may be a motherboard. The CPU 303 on the package substrate 305 is an example of an electronic device assembly that may have a structure formed in accordance with embodiments such as described above. A variety of other system components, including, but not limited to memory and other components discussed below, may also include assembly structures formed in accordance with the embodiments described above.

The system 301 further may further include memory 309 and one or more controllers 311a, 311b . . . 311n, which are also disposed on the motherboard 307. The motherboard 307 may be a single layer or multi-layered board which has a plurality of conductive lines that provide communication between the circuits in the package 305 and other components mounted to the board 307. Alternatively, one or more of the CPU 303, memory 309 and controllers 311a, 311b . . . 311n may be disposed on other cards such as daughter cards or expansion cards. The CPU 303, memory 309 and controllers 311a, 311b. . . 311n may each be seated in individual sockets or may be connected directly to a printed circuit board. A display 315 may also be included.

Any suitable operating system and various applications execute on the CPU 303 and reside in the memory 309. The content residing in memory 309 may be cached in accordance with known caching techniques. Programs and data in memory 309 may be swapped into storage 313 as part of memory management operations. The system 301 may comprise any suitable computing device, including, but not limited to, a mainframe, server, personal computer, workstation, laptop, handheld computer, handheld gaming device, handheld entertainment device (for example, MP3 (moving picture experts group layer-3 audio) player), PDA (personal digital assistant) telephony device (wireless or wired), network appliance, virtualization device, storage controller, network controller, router, etc.

The controllers 311a, 311b . . . 311n may include one or more of a system controller, peripheral controller, memory controller, hub controller, I/O (input/output) bus controller, video controller, network controller, storage controller, communications controller, etc. For example, a storage controller can control the reading of data from and the writing of data to the storage 313 in accordance with a storage protocol layer. The storage protocol of the layer may be any of a number of known storage protocols. Data being written to or read from the storage 313 may be cached in accordance with known caching techniques. A network controller can include one or more protocol layers to send and receive network packets to and from remote devices over a network 317. The network 317 may comprise a Local Area Network (LAN), the Internet, a Wide Area Network (WAN), Storage Area Network (SAN), etc. Embodiments may be configured to transmit and receive data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. An electronic assembly comprising:
a heat spreader;
a die;
a thermal interface material positioned between the thermally conductive heat spreader and the die;
the die having a first die surface facing the thermal interface material, the first die surface including a convex curvature;
the heat spreader having a first heat spreader surface facing the thermal interface material, the first heat spreader surface including a concave curvature; and
the thermal interface material including a convex surface coupled to the first heat spreader surface, and the thermal interface material including a concave surface coupled to the first die surface.

2. The electronic assembly of claim 1, wherein the thermal interface material has a substantially uniform thickness between the die and the heat spreader.

3. The electronic assembly of claim 1, wherein the thermal interface material comprises a solder.

4. The electronic assembly of claim 1, wherein the die includes a second die surface, the second die surface being coupled to a substrate.

5. The electronic assembly of claim 4, wherein the heat spreader further comprises leg regions, and the leg regions are positioned in contact with a sealant material on the substrate.

6. The electronic assembly of claim 1, wherein the concave surface of the heat spreader has a depth of curvature in the range of 30 μm to 300 μm.

7. The electronic assembly of claim 1, wherein the thermal interface material has a thickness that is less than the depth of curvature of the concave surface of the heat spreader.

8. The electronic assembly of claim 1, wherein the thermal interface material has a thickness that is less than that of the die.

9. An electronic assembly comprising;
a die coupled to a substrate, the die including a curved surface;
a thermal interface material having a first curved surface and a second curved surface, the first curved surface coupled to the curved surface of the die; and
a heat spreader including a curved surface;
wherein the curved surface of the heat spreader is coupled to the second curved surface of the thermal interface material.

10. The electronic assembly of claim 9, wherein the thermal interface material has a substantially uniform thickness between the die and the substrate.

11. The electronic assembly of claim 9, wherein the curved surface of the die and the curved surface of the heat spreader each have a depth of curvature in the range of 30 μm to 300 μm.

12. The electronic assembly of claim 9, wherein the thermal interface material has a thickness that is less than the depth of curvature of the concave surface of the heat spreader.

13. The electronic assembly of claim 9, wherein the thermal interface material comprises a solder.

14. The electronic assembly of claim 9, wherein the thermal interface material comprises a polymer.

15. A method for forming an electronic assembly, comprising:
positioning a thermal interface material on a curved surface of a die;
positioning a heat spreader having a curved surface on the thermal interface material, to form a stack including the die, the thermal interface material, and the heat spreader, wherein the curved surface of the heat spreader is positioned to face the thermal interface material, and wherein the thermal interface material is positioned between the curved surface of the die and the curved surface of the heat spreader; and
applying a force to the stack and heating the thermal interface material to a suitable temperature to couple the heat spreader to the die through the thermal interface material.

16. The method of claim 15, further comprising forming the thermal interface material to have a substantially uniform thickness between the die and the heat spreader

17. The method of claim 15, wherein the positioning a thermal interface material on the curved surface of a die comprises positioning a solder preform on the curved surface of the die, and wherein the heating the thermal interface material to a suitable temperature comprises heating to reflow the solder preform.

18. The method of claim 15, further comprising, prior to the positioning the heat spreader:
forming the curved surface of the heat spreader to include a first plurality of metallization layers, and
forming the die to include a second plurality of metallization layers.

19. The method of claim 15, wherein the positioning a thermal interface material on the curved surface of a die comprises positioning a material comprising a polymer on the curved surface of the die.
